(19) United States
(12) Patent Application Publication
(10) Pub. No.: US 2025/0244391 A1
(43) Pub. Date: Jul. 31, 2025

(54) VOLTAGE DATA CAPTURE CIRCUITS AND TECHNIQUES

(71) Applicant: Texas Instruments Incorporated, Dallas, TX (US)

(72) Inventors: Peng Cao, Allen, TX (US); Kevin Scoones, San Jose, CA (US); Chandradevi Ulaganathan, McKinney, TX (US); Vishnu Ravinuthula, Dallas, TX (US); Chienyu Huang, Plano, TX (US)

(21) Appl. No.: 18/422,291

(22) Filed: Jan. 25, 2024

(51) Int. Cl. G01R 31/3835; H01M 10/42; H01M 10/48; H03F 3/45

(52) U.S. Cl. CPC G01R 31/3835; H01M 10/425; H01M 10/482; H03F 3/45475

(57) ABSTRACT

Voltage data capture circuits and techniques. In one example, a circuit includes a differential transconductance stage, a differential transimpedance stage, and an analog to digital converter (ADC). The differential transconductance stage is configured to convert a differential input voltage into a differential current, and the differential transimpedance stage is configured to convert the differential current into a differential output voltage. The ADC is configured to sample the differential output voltage to produce a digital output signal. The circuit may further include a common-mode voltage regulator configured to regulate a common-mode input voltage for the differential transimpedance stage. The circuit can be used, for instance, in a battery monitoring system, or other voltage monitoring application.

### TECHNICAL FIELD

This description relates to data capture devices, and more particularly, to voltage data capture circuits and techniques.

### BACKGROUND

There are numerous circuit applications in which it is desirable to ensure a given voltage supply is within a range acceptable to the given application. For example, automotive applications use a battery (or set of batteries) to provide various voltage supplies to circuitry of the vehicle, and the voltage of those supplies must be within a target range for the circuitry to function properly. Accordingly, a voltage monitoring circuit can be used to provide samples of the voltage being monitored. The sampled voltage is input to an analog-to-digital converter, which in turn provides digital output data representative of the monitored voltage. If the monitored voltage is found to be out of tolerance, remedial action can be taken. However, a number of non-trivial issues remain with respect to accurate voltage measurement/monitoring, particularly in high voltage applications.

### SUMMARY

According to one example, a circuit comprises a differential transconductance stage configured to convert a differential input voltage into a differential current, a differential transimpedance stage configured to convert the differential current into a differential output voltage, a common-mode voltage regulator configured to regulate a common-mode input voltage for the differential transimpedance stage, and an analog-to-digital converter configured to sample the differential output voltage to produce a digital output signal.

According to another example, a circuit comprises a differential transimpedance amplifier having a first input terminal, a second input terminal, a first output terminal, and second output terminal, and a differential transconductance stage including a first transistor coupled in series between a voltage supply terminal and the first input terminal of the differential transimpedance amplifier, and a second transistor coupled in series between the voltage supply terminal and the second input terminal of the differential transimpedance amplifier. The differential transconductance stage further comprises a first unity gain buffer having a first input terminal coupled to a first input voltage terminal, a second input terminal coupled to the voltage supply terminal, and an output coupled to a control terminal of the first transistor, a second unity gain buffer having a first input terminal coupled to a second input voltage terminal, a second input terminal coupled to the voltage supply terminal, and an output coupled to a control terminal of the second transistor, and a resistor coupled between the second input terminal of the first unity gain buffer and the second input terminal of the second unity gain buffer. The circuit further comprises an analog-to-digital converter having a first input terminal and a second input terminal coupled to the first output terminal and the second output terminal, respectively, of the differential transimpedance amplifier.

According to another example, a circuit comprises a differential transconductance stage configured to produce a differential current based on first and second input voltages received at first and second input voltage terminals, respectively. The differential transconductance stage comprises a first unity gain buffer having a first and second input terminals switchably coupled to the first input voltage terminal and a voltage supply terminal, a second unity gain buffer having first and second input terminals switchably coupled to the second input voltage terminal and the voltage supply terminal, and a resistor coupled between the first and second unity gain buffers. The circuit further comprises a differential transimpedance stage coupled to the differential transconductance stage and configured to convert the differential current into a differential output voltage, and chop circuitry having a clock terminal and configured to switch the first and second input terminals of each of the first and second unity gain buffers according to a frequency of a chop clock signal received via the clock terminal.

### BRIEF DESCRIPTION OF THE DRAWINGS

FIG. 1 is a block diagram of a battery monitoring system, in an example.

FIG. 2 is a block diagram of a battery monitoring signal chain, in an example.

FIG. 3 is a block diagram illustrating differential voltage measurement circuitry, in an example.

FIG. 4 is a block diagram illustrating the differential voltage measurement circuitry of FIG. 3 including chop circuitry, in an example.

FIG. 5 is a schematic diagram the differential voltage measurement circuitry of FIG. 3, in another example.

FIG. 6A is a circuit diagram illustrating an operational amplifier as may be included in the differential voltage measurement circuitry of FIGS. 3-5, in an example.

FIG. 6B is a circuit diagram illustrating circuitry forming part of the operational amplifier of FIG. 6A, in an example.

FIG. 6C is a circuit diagram illustrating an example of chop circuitry for the operational amplifier of FIG. 6A, in an example.

FIG. 7 is a schematic diagram illustrating an analog-to-digital converter including chop circuitry, as may be included in the differential voltage measurement circuitry of FIGS. 3-5, in an example.

### DETAILED DESCRIPTION

Techniques are described for acquiring voltage measurements. The techniques may be used in a variety of circuits and systems, including battery monitoring systems, for example. As described in more detail below, the techniques can be used to provide a fully differential signal chain to achieve high measurement accuracy (e.g., better than 2 millivolt DC accuracy) and relatively low noise floor over a measurement voltage range that can range from negative voltages to positive voltages (e.g., −2 volts to 5.5 volts). In an example, a circuit includes a differential transconductance stage, a differential transimpedance stage, and an analog to digital converter (ADC). The differential transconductance stage is configured to convert a differential input voltage into a differential current, and the differential transimpedance stage is configured to convert the differential current into a differential output voltage. The ADC is configured to sample the differential output voltage to produce a digital output signal. The circuit may further include a common-mode voltage regulator configured to regulate a common-mode input voltage for the differential transimpedance stage. As described further below, in some such examples, the differential transconductance stage includes a pair of unity-gain buffers. In addition, in some examples, the circuit includes an offset stage configured to adjust the differential current converted by the differential transimpedance stage based on an input range of the ADC to reduce input-referred error of the ADC. The circuit can be used, for instance, in a battery monitoring application. These and other aspects are described in more detail below.

### General Overview

As noted above, a number of non-trivial issues are associated with performing accurate voltage measurements in voltage monitoring applications. For example, in certain measurement systems, raw DC error may limit the accuracy of the measurements that can be achieved. Raw DC error (or simply raw error) refers to the error in the DC (direct current) voltage measurement channel. One possible solution to this problem is to perform, during manufacture of the voltage measurement system, digital calibration in an effort to compensate for such channel error. However, in some instances, the desired tolerance of the voltage being monitored may exceed the test measurement accuracy, thus still leaving limited accuracy post calibration. For example, in some instances having a tolerance of +/−2 millivolts for a voltage in the range of 0.5 volts to 5.5 volts, the digital calibration may overcompensate for the channel error whereas in other instances it may undercompensate. Moreover, future generations of voltage monitoring circuitry may be expected to support lower noise density (noise floor) and wider input voltage ranges (e.g., −2 volts to 5.5 volts) with even tighter tolerances.

Accordingly, voltage measurement circuits are described herein that may support lower noise density and provide improved test measurement accuracy, relative to other voltage measurement techniques. Furthermore, as described below, in some examples, the voltage measurement devices may support a relatively wide input voltage range, including a negative input voltage. According to certain examples, a voltage data capture device for voltage measurements implements a fully differential signal chain to achieve these and other benefits. In certain examples, the fully differential signal chain includes an analog front-end that has a differential transconductance (GM) stage and a differential transimpedance (TIA) stage, and that is followed by a unity-gain delta-sigma analog-to-digital converter (ADC). In an example, the differential transconductance stage may support a relatively high input voltage (e.g., 150V common mode), and includes a pair of low-voltage unity gain buffers and a resistor that together generate a differential current proportional to a differential input voltage. The low-voltage differential transimpedance stage converts the differential current into differential voltage with a selected gain. In some examples, the analog front-end includes an offset stage to center a unipolar input about zero in order to maximize the gain of the analog front-end, as described further below. The ADC digitizes the differential voltage supplied from the transimpedance stage to produce a digital measurement of the input voltage. By using a fully differential signal chain, common-mode noise can be eliminated, or otherwise reduced to a negligible level, thereby significantly lowering noise density and improving the measurement accuracy by reducing channel raw error. As described in more detail below, an integrated solution including the analog front-end and delta-sigma ADC can produce signal measurements with sufficiently low raw error to potentially avoid the need for digital calibration, and thus further avoid limitations with respect to accuracy of test equipment that might be used for calibration.

### System Architecture

Battery monitoring is an example of an application in which it can be desirable to provide accurate voltage measurements. For example, there are numerous systems and devices, including electric vehicles, computing devices, etc., where it is desirable to monitor the state of charge of the system/device batteries to provide estimates of the remaining charge and therefore the remaining amount of time for which the system or device can be used until the batteries must be recharged. In certain systems or devices, such as electric vehicles, for example, accurate battery voltage measurements can be important to notify users of how much remaining usage time (e.g., driving range for an electric vehicle) is available. Likewise, it may be desirable to monitor the various supply voltages that are derived from such batteries, to ensure that the various systems being powered operate correctly.

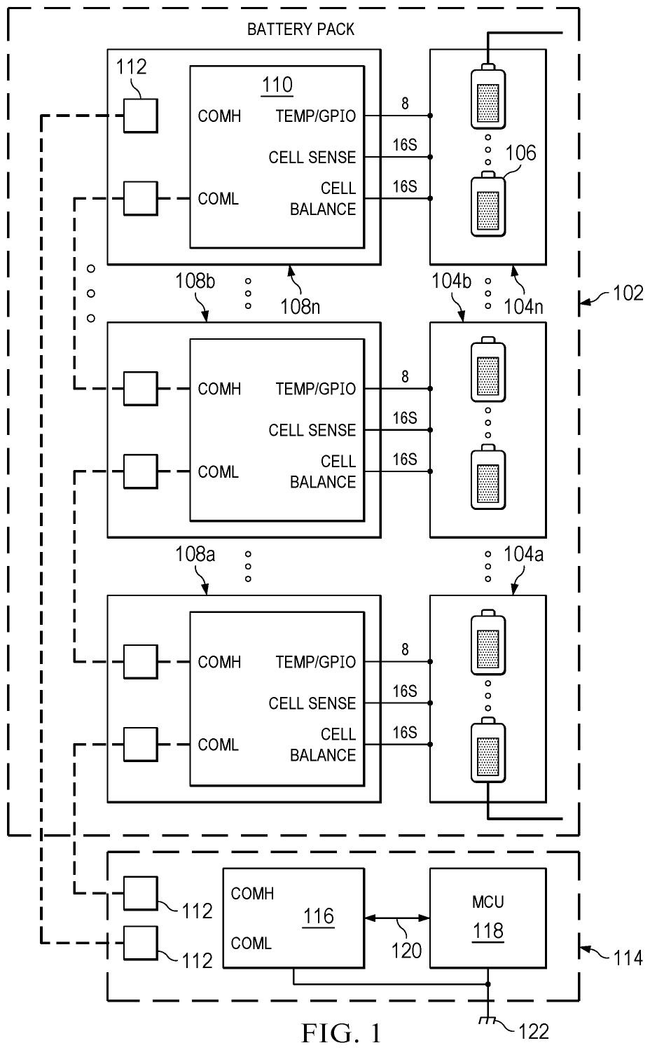

FIG. 1 is a block diagram of a battery monitoring system in which circuitry, according to an example. A battery pack 102 includes a plurality of battery sets 104 (identified individually as battery sets 104a, 104b, . . . , 104n) that each include one or more battery cells 106. Battery monitoring devices 108 (identified individually as battery monitoring devices 108a, 108b, . . . , 108n) are coupled to the battery sets 104. In some applications, such as battery monitoring for electric vehicles, the total voltage across the battery pack 102 may be relatively high, for example, up to about 800V or more. Since a single battery monitoring device 108 may not be able to accurately measure the full voltage of the battery pack 102, the battery cells 106 of the battery pack 102 may be grouped into the plurality of battery sets 104, such that individual battery monitoring device 108a-n measure the voltage across corresponding battery sets 104a-n. Accordingly, the battery monitoring system of FIG. 1 may be referred to as a “stackable battery monitor” because the battery monitoring devices 108a-n may be “stacked” and connected together as shown in FIG. 1. For example, the battery monitoring device 108a may read the voltage from the battery set 104a and provide an output measurement signal to the battery monitoring device 108b. The battery monitoring device 108b in turn reads the voltage from the battery set 104b, and provides an output measurement signal (that includes its own measurement and the measurement received from the battery monitoring device 108a) to the next battery monitoring device in the stack. This arrangement continues to the last battery monitoring device 108n in the stack, which provides a final grouped measurement from the complete stack to a base device 114.

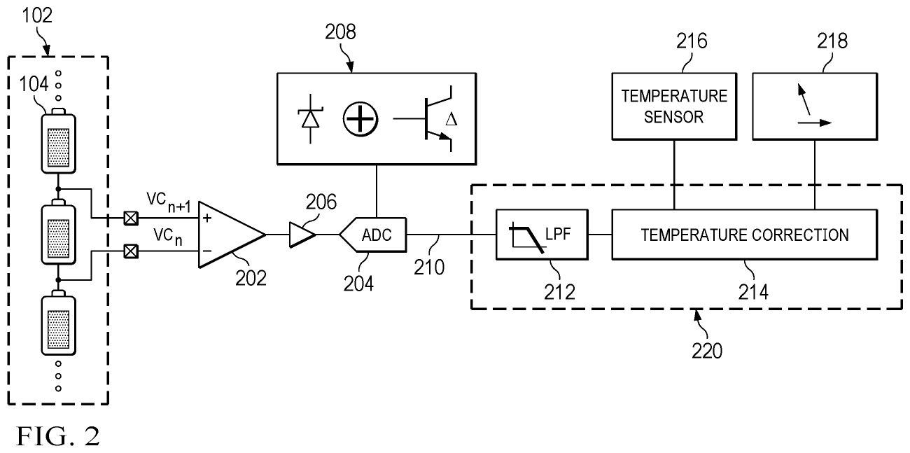

The base device 114 includes a base component 116 that collects the voltage measurements from the stack of battery monitoring devices 108a-n as described above. The battery monitoring devices 108a-n, and the base component 116, may be connected together via high-voltage insolation elements 112, as shown. Each of the battery monitoring devices 108a-n includes a voltage measurement device 110, which may include voltage data capture circuitry as described further below with reference to FIGS. 2-7. In the base device 114, the base component 116 is coupled to a microcontroller unit (MCU) 118. The base component 116 communicates with the MCU 118 via a serial communication interface, as indicated at 120. For example, the base component 116 may provide information representative of the voltage measurement of the battery pack 102 to the MCU 118. The MCU 118 may include, for instance, input and output ports and a processor or otherwise be configured to process this information, use the information in various ways according to the application in which the battery monitoring system is being used, and/or communicate the information to one or more external systems or devices. The base component 116 and the MCU 118 may be coupled to a ground reference 122, such as a chassis of an electric vehicle, for example.

FIG. 2 illustrates an example of a battery monitoring signal chain or circuit as may be employed in the system of FIG. 1, for example. Such a battery monitoring signal circuit may be implemented, for instance, within each of the voltage measurement devices 110. As shown, an analog front-end 202 is coupled across a battery set 104 and measures a differential voltage (difference between VCₙ₊₁ and VCₙ). Although only one signal chain is shown in FIG. 2, corresponding analog front-ends 202 may be coupled across each battery set 104 in the battery pack 102 to allow for simultaneous measurement of the voltages at each battery set 104. As described above with reference to FIG. 1, each battery set 104 may include one or more battery cells 106.

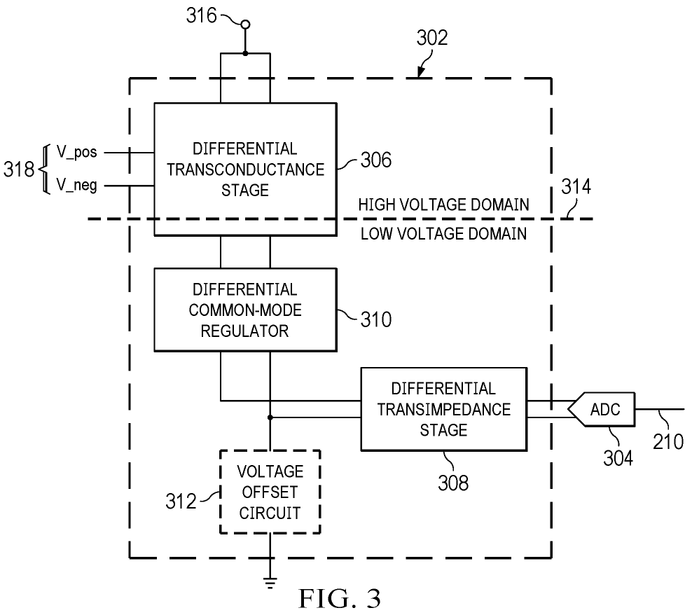

The analog front-end 202 provides an output measurement signal, corresponding to the measurement of the voltage at the corresponding battery set 104, to an analog-to-digital converter (ADC) 204. In some examples, a buffer 206 is coupled between the analog front-end 202 and the ADC 204, as shown in FIG. 2. Examples of the analog front-end 202 are described further below with reference to FIGS. 3-7.

The ADC 204 digitizes the output measurement signal received from the analog front-end 202 and provides a digital sample 210 of the voltage at the battery set 104 to digital circuitry 220. Reference circuitry 208 provides an operating voltage range for the ADC 204. In the illustrated example, the digital circuitry 220 includes a digital low pass filter 212 and temperature correction circuitry 214. In some examples, the temperature correction circuitry 214 is configured to provide digital compensation or correction for temperature variations in the battery pack 102 that may influence the voltage measurements. The temperature correction circuitry 214 may be coupled to a temperature sensor 216 that provides temperature measurements. In some examples, the temperature correction circuitry 214 is configured to provide second-order temperature correction (based on three temperature measurements from the temperature sensor 216). In other examples, the temperature correction circuitry 214 may be configured to provide third-order temperature correction (based on four temperature measurements from the temperature sensor 216). In some examples, the digital circuitry 220 is further coupled to a strain gauge 218 that may provide additional measurements that can be used to provide digital correction for the voltage measurements obtained from the analog front-end 202.

As shown in FIG. 2, the analog front-end 202 provides the initial voltage measurement from the battery pack 102 to the ADC for digitization and further processing. In some examples, the analog front-end 202 provides a single-ended output signal that is to one terminal of a relatively large resistor (e.g., 600 kiloohms), with the other terminal of the resistor coupled to a voltage reference. The inputs of ADC 204 are coupled across the resistor, to produce the input signal for the ADC 204. This large output impedance from the analog front-end 202 makes it sensitive to input-referred noise or kickback from the ADC 204 and may result in poor linearity. Furthermore, in single-ended configurations, only the positive half of the input voltage range for the ADC 204 is used. In some examples, the analog front-end 202 can be configured to use auto-zero techniques to remove voltage offsets; however, in such instances, the noise floor may be high due to aliasing. For instance, in an application including main and nulling amplifiers, an example auto-zero technique may involve measuring the offset voltage of a nulling amplifier during a first clock phase and storing the measurement value on a first sample-and-hold capacitor, and measuring and storing (on a second sample-and-hold capacitor) the offset voltage of the main amplifier during a second clock phase. The overall offset can then be applied to the main amplifier while processing the input signal. Because such an auto-zeroing technique uses sampling to correct offset, sampling can cause noise to be aliased back into the baseband, and therefore, such auto-zero amplifier configurations can suffer from relatively high in-band noise. To suppress noise, more current can be used; however, this results in higher power dissipation, which may be undesirable in some applications.

To address such drawbacks, associated with a single-ended frontend 202, the analog front-end 202 may include a fully differential measurement signal channel to provide a differential output measurement signal to the ADC 204. Relative to single-ended configurations, fully differential configurations of the analog front-end 202, such as described below with reference to FIGS. 3-7, may provide a significantly improved common-mode rejection ratio (CMRR) and power supply rejection ratio (PSRR). For instance, some examples of a fully differential analog front-end as described herein may achieve a common-mode rejection ratio of greater than 100 dB over an input voltage range of 0-100V. Thus, such implementations may achieve a significantly lower noise floor. Furthermore, by providing a differential output measurement signal, and possibly using an offset stage to center the voltage around zero, the need for auto-zero techniques can be avoided and the full input voltage range of the ADC 204 may be utilized, as described further below.

### Example Circuit Implementations

Referring to FIG. 3, there is illustrated a block diagram of voltage measurement circuitry including an analog front-end 302 coupled to an ADC 304, according to one example. The analog front-end 302 may be used to implement a fully differential version of the analog front-end 202 in the signal chain of FIG. 2, in some examples. Further, in some examples, the ADC 304 corresponds to, or may be used to implement, the ADC 204 in the signal chain of FIG. 2. In some examples, the ADC 304 is a unity gain delta-sigma ADC 304 that receives a differential measurement signal from the analog front-end 302 and provides the digitized sample 210. As described above, configuring analog front-end 302 to provide a fully differential signal chain that may achieve significant advantages over single-ended configurations in comparable applications.

In some examples, the analog front-end 302 includes a differential transconductance stage 306, a differential transimpedance stage 308, and a differential common-mode regulator 310. The analog front-end 302 may further include a voltage offset circuit 312. Each of these components are described further below.

The differential transconductance stage 306 may be coupled to a voltage supply terminal 316, and accepts an input voltage 318. The supply voltage provided at the voltage supply terminal 316 may be a relatively high voltage, for example, around 100V. In the example illustrated in FIG. 3, the input voltage 318 includes a first voltage V_pos and a second voltage V_neg. In some examples, these voltages, V_pos and V_neg, correspond to the voltages VCₙ₊₁ and VCₙ across a battery set 104 described above with reference to FIGS. 1 and 2. In some examples, the differential transconductance stage 306 operates at least partially in the high-voltage domain, for example, accepting input voltages V_pos and V_neg in a range of 80V-150V in some applications. However, the differential input voltage, that is the difference between V_pos and V_neg, may be relatively low, for example, in a range of about −0.05V to 6V. Thus, the remaining circuitry (e.g., the differential transimpedance stage 308, the differential common-mode regulator 310, and the voltage offset circuit 312) of the analog front-end 302 may operate in the low-voltage domain. In FIG. 3, separation between the high-voltage domain and the low-voltage domain is indicated by line 314. The differential transconductance stage 306 produces, based on the differential input voltage 318, a differential current that is supplied to the differential transimpedance stage 308. In some examples, the differential current is proportional to the differential input voltage 318.

The differential transimpedance stage 308 converts the differential current received from the differential transconductance stage 306 into a differential voltage that is output to the ADC 304. In some examples, the differential common-mode regulator 310 operates to stabilize the common mode voltage at the input to the differential transimpedance stage 308, as described further below.

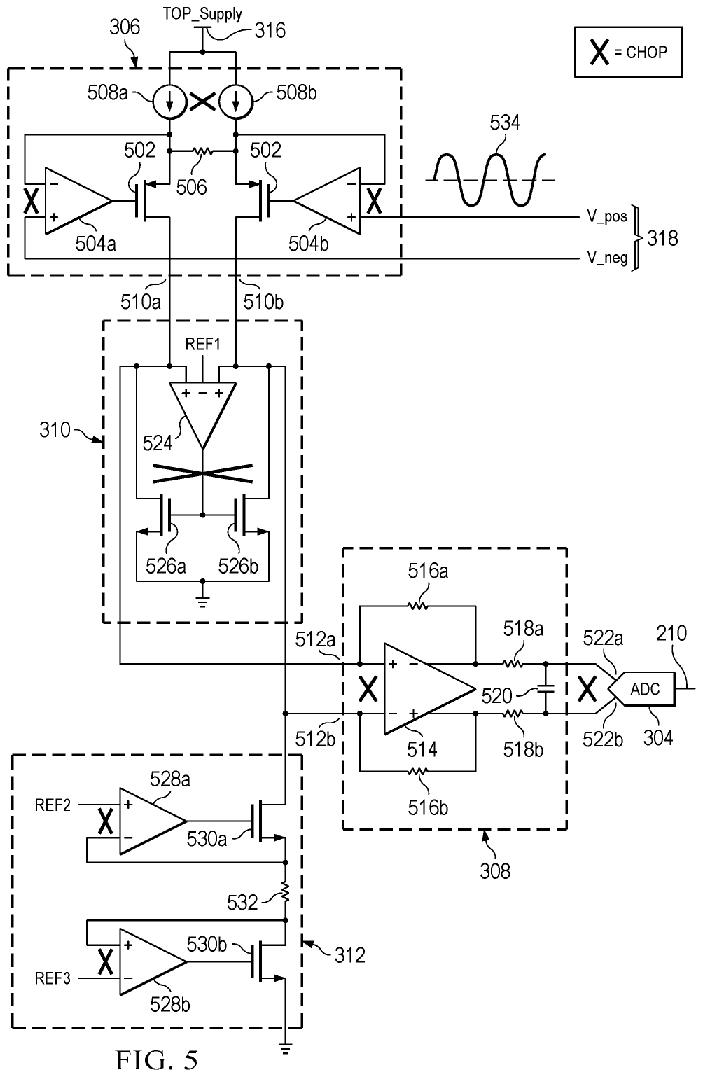

According to certain examples, some or all of the differential transconductance stage 306, the differential transimpedance stage 308, the differential common-mode regulator 310, the voltage offset circuit 312, and/or the ADC 304 may be implemented using one or more amplifiers, as described further below with reference to FIGS. 5-7. In some examples, some or all of the inputs of these various amplifiers are “chopped” (e.g., their inputs are rapidly swapped) and the outputs “de-chopped” (e.g., rapidly swapped in the same manner as the inputs). As a result, the voltage output from the amplifier has the desired voltage level, but the offset is modulated according to the chop frequency (e.g., the frequency at which the chopping occurs, such as the frequency at which the amplifier inputs are switches). The use of chopping may reduce offset and “flicker” noise (e.g., 1/f noise) without the drawbacks associated with using auto-zero techniques. As described above, using auto-zero techniques to remove offsets can lead to a high noise floor due to aliasing. In contrast, using chopping, the offset and flicker noise can be removed to produce a relatively clean noise floor with little to no noise being aliased back into the signal.

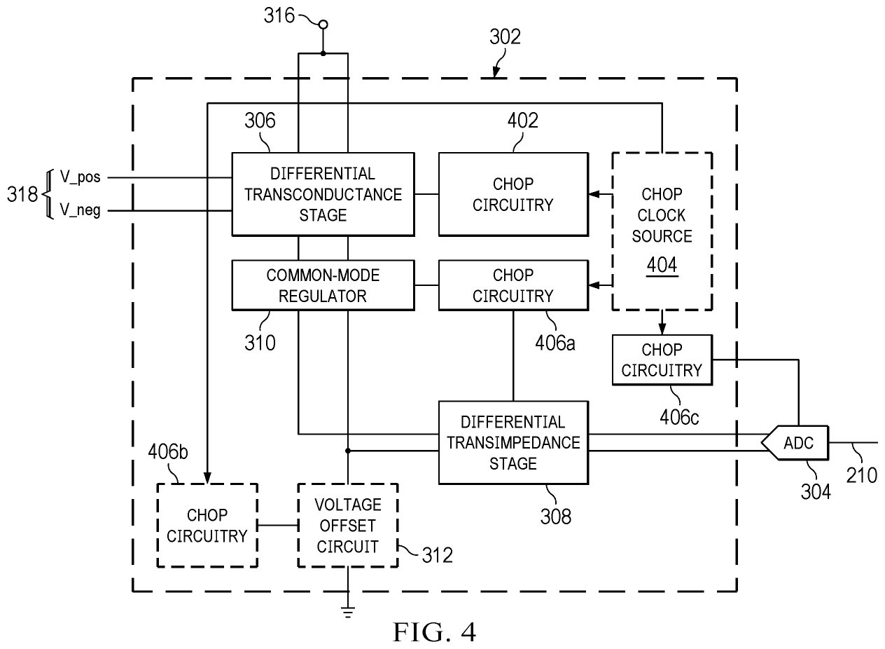

Thus, referring to FIG. 4, in some examples, the analog front-end 302 includes chop circuitry to implement the chopping (and de-chopping) functions at the various amplifiers and/or other circuitry inputs/outputs. As described in more detail below, in some examples, the differential transconductance stage 306 includes a pair of unit-gain buffers, which may be implemented using operational amplifiers. In some examples, chop circuitry 402 is used to implement chopping at those unity-gain buffers. As described above, the input voltages V_pos and V_neg may include relatively high voltages, and thus the differential transconductance stage 306 operates at least partially in the high-voltage domain, as illustrated in FIG. 3. Accordingly, and as described in more detail below, techniques may be implemented in the differential transconductance stage 306 and the chop circuitry 402 to generate a virtual low-voltage environment within the high-voltage domain, such that the chopping implemented by the chop circuitry 402 can be performed at low voltages. In some examples, the chop circuitry 402 is coupled to the differential transconductance stage 306. In other examples, some or all of the chop circuitry 402 may be part of the differential transconductance stage 306.

The chop circuitry 402 operates to perform the chopping at a chop frequency that is set by a chop clock signal. Accordingly, in some examples, the analog front-end 302 includes a chop clock source 404. In other examples, the chop clock source may be external to the analog front-end 302 and the chop clock signal may be received via an input/output terminal, for example.

In the low-voltage domain (below the line 314 in FIG. 3), chop circuitry 406 can be used to implement chopping at some or all of the amplifiers included in components of the analog front-end 302 and/or the ADC 304. In some examples, the analog front-end 302 includes chop circuitry 406a that performs chopping in the differential transimpedance stage 308 and/or the common-mode regulator 310. The chop circuitry 406a may be part of the differential transimpedance stage 308 and/or the common-mode regulator 310, or may be coupled to components of the differential transimpedance stage 308 and/or the common-mode regulator 310. In examples in which the analog front-end 302 includes the voltage offset circuit 312, the analog front-end 302 may additionally include chop circuitry 406b. The chop circuitry 406b may be coupled to, and/or part of, the voltage offset circuit 312. In some examples, the analog front-end 302 further includes chop circuitry 406c that may be coupled to the ADC 304. In other examples, the chop circuitry 406c may be external to the analog front-end 302. The chop circuitry 406a, 406b, and 406c, along with the chop circuitry 402, may be coupled to the chop clock source 404 to receive the same chop clock signal. This may ensure that all chopping operations in the analog front-end 302 and the ADC 304 may be performed synchronously without having to account for timing variations between different chop clocks.

Referring to FIG. 5, there is illustrated a schematic diagram illustrating an example of the differential voltage measurement circuitry of FIG. 3. As described above, in this example, the differential transconductance stage 306 includes a pair of unity-gain buffers 504a, 504b that buffer the input voltage 318 across a resistor 506. As shown, the input voltage V_pos is supplied to a first input terminal of a first unity gain buffer 504a and the input voltage V_neg is supplied to a first input terminal of a second unity gain buffer 504b. Second input terminals of the first and second unity gain buffers 504a, 504b are coupled to the supply voltage terminal 316 via current sources 508a, 508b, respectively. The outputs of the first and second unity gain buffers 504a, 504b are coupled to the control terminals of respective transistors 502. When the input voltages, V_pos and V_neg, are supplied to the input terminals of the first and second unity gain buffers 504a, 504b, respectively, a current flows through the resistor 506 coupled between the two unity gain buffers 504a, 504b, and produces a differential output current at output terminals 510a, 501b of the differential transconductance stage 306.

The output terminals 510a, 510b of the differential transconductance stage 306 are coupled to input terminals 512a, 512b, respectively, of the differential transimpedance stage 308. Accordingly, the differential current produced by the differential transconductance stage 306 flows to the input terminals 512a, 512b of the differential transimpedance stage 308. The differential transimpedance stage 308 includes a transimpedance amplifier 514 having input terminals coupled to, or corresponding to, the input terminals 512a, 512b of the differential transimpedance stage 308. Feedback paths are provided from the output terminals of the transimpedance amplifier 514 to the input terminals of the transimpedance amplifier 514 via resistors 516a, 516b, respectively. The output terminals of the transimpedance amplifier 514 are coupled to input terminals 522a, 522b of the ADC 304, respectively. The transimpedance amplifier 514 converts the differential current received at the input terminals 512a, 512b to a differential output voltage that is provided to the input terminals 522a, 522b of the ADC 304.

As described above, in some single-ended implementations of the analog front-end 202, a large resistor is placed at the output to provide the single-ended input voltage to the ADC 204. As a result of this high output impedance, the analog front-end 202 may be susceptible to sampling kickback from the ADC 204. In contrast, the fully differential transimpedance stage 308 may present a low output impedance to the ADC 304, which may result in improved linearity and reduced input-referred noise from the ADC 304. According to certain examples, the differential transimpedance stage 308 includes a filter coupled between the output terminals of the transimpedance amplifier 514 and the input terminals 522a, 522b of the ADC 304. In some examples, the filter is a resistive-capacitive (RC) filter that includes a pair of series resistors 518a, 518b and a shunt capacitor 520. Thus, in this example, a first resistor 518a is coupled between an output terminal of the transimpedance amplifier 514 and the first input terminal 522a of the ADC 304, and a second resistor 518b is coupled between an output terminal of the transimpedance amplifier 514 and the second input terminal 522b of the ADC 304. The capacitor 520 is connected between the two input terminals 522a, 522b of the ADC 304. This RC filter may act as an anti-aliasing filter for the ADC 304.

As described above, the differential common-mode regulator 310 may operate to stabilize the common mode voltage at the input to the differential transimpedance stage 308. As illustrated in FIG. 5, in some examples, the differential common-mode regulator includes an operational amplifier 524 and a pair of transistors 526a, 526b. In some examples, the operational amplifier 524 has first and second (+) input terminals coupled to the first and second output terminals 510a, 510b, respectively, of the differential transconductance stage 306, and a third (−) input terminal coupled to a reference voltage terminal to receive a first reference voltage (REF1). The transistors 526a, 526b, are coupled between the output terminals 510a, 510b of the differential transconductance stage 306 and a ground terminal. An output terminal of the operational amplifier 524 is coupled to the control terminals of the transistors 526a, 526b, which are coupled together, as shown in FIG. 5. In some examples, the differential common-mode regulator 310 provides a virtual ground and stabilizes the common mode voltage at the input to the differential transimpedance stage 308 based on the first reference voltage, REF1. This may allow the voltage margin of the transimpedance amplifier 514 in the transimpedance stage 308 to be optimized. For example, because variation in the common mode voltage at the input to the differential transimpedance stage 308 may be reduced by the differential common-mode regulator 310, there may be less need to reserve a wide voltage margin to account for variation in the input common mode voltage.

As described above, in certain examples, the analog front-end 302 includes the voltage offset circuit 312 that is configured to center the range of the differential input voltage 318 about a reference point 534, such as zero volts, for example. Accordingly, in some examples, by using the voltage offset circuit 312, the center voltage at the differential inputs 512a, 512b of the transimpedance stage 308 can be made close to zero (e.g., within a tolerance acceptable to a given application, such as +/−10 millivolts, or other suitable tolerance). This allows the full operating voltage range of the ADC 304 to be used. As described above with reference to FIG. 2, the reference circuitry 208 may supply, and set, a reference voltage range for the ADC 304. For example, this range may be ±4V. Accordingly, by controlling the maximum absolute value of the voltage at the input terminals 522a, 522b of the ADC 304 to be no more than the maximum reference voltage (e.g., ≤4V) and centered about zero, the full operating range of the ADC 304, or close to it (e.g., within one or two least significant bits), can be used. For example, if the differential voltage at the input terminals 522a, 522b of the ADC 304 has a range of −1.6V to +1.6V, because the signal is fully differential, an input voltage maximum of +3.2V is produced at the ADC 304. Reversing the polarity produces an input voltage minimum of −3.2V. Thus, the differential input voltage range may be −3.2V to 3.2V, which is relatively close to the full operating range of −4V to +4V of the ADC 304 in this example. In contrast, as described above, where the analog front-end 202 is configured to provide a single-ended output voltage, rather than a differential output, only the positive half of the ADC operating voltage range can be used (e.g., 0V to +4V). Furthermore, in practical applications of such single-ended configurations, the buffer 206 may limit the low end of the usable voltage range since it may not be able to support an input voltage close to 0V (e.g., <0.5V, or other suitable tolerance). Thus, the fully differential configuration of examples of the analog front-end 302 described herein may significantly extend the usable voltage range of the ADC 304. The voltage ranges described above are provided as examples only, and numerous other voltage ranges, both the for the reference voltage of the ADC 304 and the differential input voltage, may be used.

Still referring to FIG. 5, in some examples, the voltage offset circuit 312 includes a first amplifier 528a and a second amplifier 528b. The first amplifier 528a has a first input terminal coupled to a second reference voltage terminal to receive a second reference voltage, REF2, and the second amplifier 528b has a first input terminal coupled to a third reference voltage terminal to receive a third reference voltage, REF3. Second input terminals of the two amplifiers 528a, 528b are coupled together via a resistor 532, a shown in FIG. 5. The voltage offset circuit 312 may further include first and second transistors 530a, 530b. In the illustrated example, the first transistor 530a is coupled between the output terminal 510b of the differential transconductance stage 306 and the resistor 532, and the second transistor 530b is coupled between the resistor 532 and a ground terminal. In some examples, an output terminal of the first amplifier 528a is coupled to a control terminal (e.g., a gate) of the first transistor 530a, and an output terminal of the second amplifier 528b is coupled to a control terminal of the second transistor 530b.

According to certain examples, the voltage offset circuit 312 may be enabled or disabled, depending on whether or not the differential input voltage 318 is centered about zero (or some other selected reference point). For example, in some instances, the differential input voltage is may be in a range of about −0.05V to +5.77V, and therefore is not centered about zero. Accordingly, the voltage offset circuit 312 can be enabled to center the differential voltage at the inputs to the transimpedance stage 308 about zero, for example, in a range of −3.2V to +3.2V as described above. In other examples, the differential input voltage 318 may already be centered around zero, for example, in a range of −2.91V to +2.91V, and therefore there may be no need to recenter the differential voltage at the inputs to the transimpedance stage 308. Accordingly, in such instances, the voltage offset circuit 312 may be disabled.

In some examples, the voltage offset circuit 312 is configured to produce subtraction of a certain offset voltage from the differential input voltage 318 in order to center the differential voltage at the inputs to the transimpedance stage 308 about zero. This offset voltage may be set by the ratio of the values of the resistor 532 and the resistor 506. For example, if the resistor 506 has a value of 20R (R being some constant value that may be selected depending on a particular application and/or circuit design) and the resistor 532 has a value of 7R, the voltage subtracted by the voltage offset circuit is given by 20R/7R=2.86V. For the above example in which the differential input voltage 318 is in the range of −0.05V to +5.77V, subtracting 2.86V (or adding-2.86V) with the voltage offset circuit 312 recenters the voltage range at −2.91V to +2.91V.

Thus, to achieve re-centering of the input voltage to the ADC 304, the voltage offset circuit 312, when enabled, adds the offset voltage amount to the ADC input. However, to maintain accurate measurement results, when something is added to the ADC input, it may also be necessary to remove it from the ADC output. However, unless the addition can be accurately measured and/or tracked, removing it accurately can be difficult. Accordingly, to address this concern, the voltage offset circuit 312 may be configured to operate based on the ADC reference voltage, Vref. In some examples, the reference voltages, REF2 and REF3, input to the first and second amplifiers 528a, 528b, respectively, are derived from the ADC reference voltage using a voltage divider. In one example, the reference voltages, REF2, REF3, are selected such that REF3-REF2=0.5Vref. As a result, the offset voltage added by the voltage offset circuit 312 tracks the ADC reference voltage and the accuracy of the offset voltage is not sensitive to drift in the reference voltage. Accordingly, the offset voltage can be removed by the digital logic within the ADC 304, using a fixed gain correction. In some examples, the fixed digital gain can be implemented as a shift adder, which may use far fewer digital logic gates than a multiplier, for example.

As described above, in some examples, chopping is used to reduce noise in the signal chain. Referring to FIGS. 3-5, in the low voltage domain (below line 314 in FIG. 3), the chop circuitry 406a can be used to swap the input terminals of the transimpedance amplifier 514 and the amplifier 524. Similarly, the chop circuitry 406b can be used to swap the inputs of the first amplifier 528a and of the second amplifier 528b, as indicated in FIG. 5. Further, the chop circuitry 406c can be used to swap the inputs 522a, 522b of the ADC 304. However, as described above, the voltages V_pos and V_neg input to the amplifiers 504a, 504b, respectively, of the differential transconductance stage 306 may be relatively high voltages, such as 90V, 95V, 100V, or higher, and therefore, the chop circuitry 402 may need to perform a high-voltage chop. Accordingly, in some examples, techniques are employed to implement a virtual low-voltage environment within the high voltage domain (above the line 314 in FIG. 3) so as to allow low-voltage chopping to be implemented in the high-voltage domain portion of the differential transconductance stage 306.

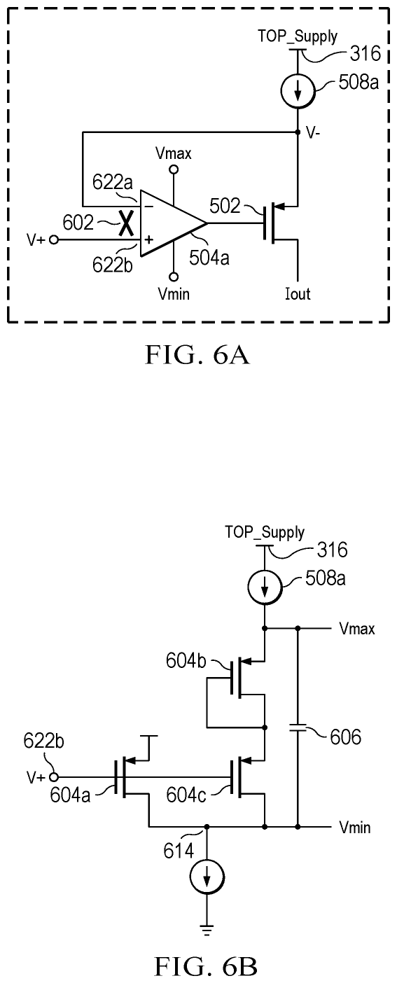

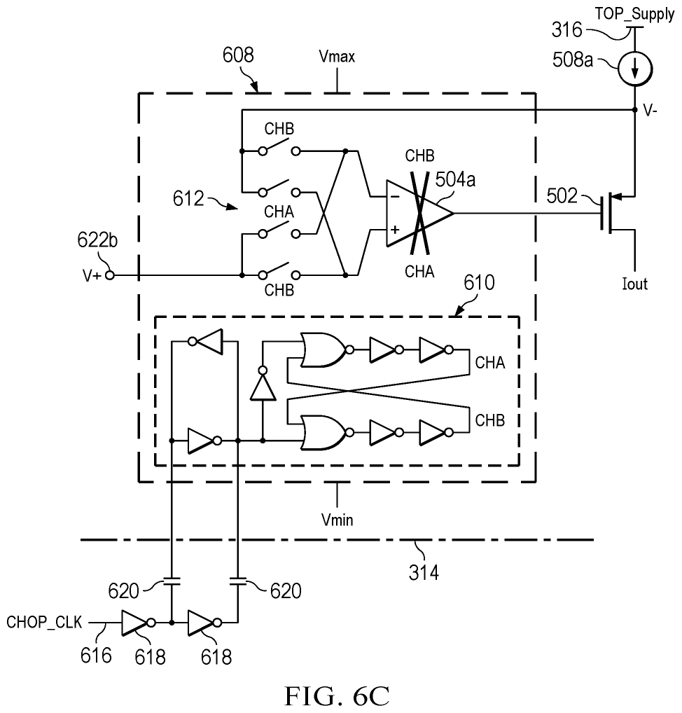

Referring to FIGS. 6A-C, examples of the chop circuitry 402 applied to the first unity-gain buffer 504a are illustrated. Although the following description refers to the first unity-gain buffer 504a, the same circuitry and techniques may be applied to the second unity-gain buffer 504b.

As shown in FIG. 6A, the first unity-gain buffer includes first and second input terminals 622a, 622b. These input terminals 622a, 622b are chopped, as indicated by 602, using the chop circuitry 402. The first input terminal 622a is coupled to the current source 508a and the second input terminal 622b receives the input voltage, V_pos (V+). The current source 508a is coupled to the supply voltage terminal 316. As described above, in some examples, the supply voltage provided at the supply voltage terminal 316 is a relatively high voltage, for example, 100V. Further, the input voltage V+ can be a relatively high voltage, for example, 90V. Thus, the chop circuitry 402 may operate within this high-voltage domain. According to certain examples, local supply voltages for the first unity-gain buffer 504a, as well as local grounds and the chop signals to operate the chop circuitry 402 are generated locally at the first unity-gain buffer 504a based on the input voltage V+. Thus, a floating local supply voltage, Vmax, a floating local ground, Vmin, and the chop signals can be generated locally to track the voltage, V+ (“pin voltage”), at the second input terminal 522b of the first unity-gain buffer 504a.

FIG. 6B illustrates circuitry that can be used to produce the floating ground, Vmin, and floating local supply voltage, Vmax. As shown, in this example, the circuitry includes a first transistor 604a coupled to the second input terminal 622b and to a terminal 614, and second and third transistors 604b, 604c coupled between the current source 508a and the terminal 614. A capacitor 606 is coupled in parallel with the second and third transistors 604b, 604c. In some examples, the first transistor 604a produces a voltage at the terminal 614 that is one gate-source drop (Vgs) below the input voltage V+. This voltage can be used as the floating ground, Vmin. The floating local supply voltage, Vmax, is produced from the input voltage, V+, by two gate-source increments through the second and third transistors 604b, 604c. Thus, in this example, the local supply voltage, Vmax is equal to the input voltage, V+, plus 2Vgs, and Vmin is equal to the input voltage, V+ minus 1Vgs. Once the local floating power supply, Vmax, and the local floating ground, Vmin, have been generated, they can be used as the power supply for the first unity-gain buffer 504a and for the chop circuitry and signals, as shown in FIG. 6C.

Although the local floating power supply, Vmax, and the local floating ground, Vmin, are produced based on the input voltage, V+, and are therefore in the high-voltage domain, the difference between them may be small (e.g., 3Vgs). Thus, referring to FIG. 6C, a virtual low-voltage environment 608, with respect to the floating ground, Vmin, can be created within the high-voltage domain. Accordingly, chop circuitry that can be used to chop the input terminals 622a, 622b of the first unity-gain buffer 504a can operate within this virtual low-voltage environment 608. In some examples, this circuitry includes digital logic circuitry 610 and a switch network 612, both of which may be part of the chop circuitry 402 of FIG. 4. The chop clock signal 616 is produced from the chop clock source 404, which may be part of or external to the analog front-end 302. The chop clock signal 616 is in the low-voltage domain (e.g., 0V-5V). Accordingly, capacitors 620 are used to isolate and decouple the low-voltage domain from the high-voltage domain.

According to certain examples, the digital logic circuitry 610 generates two switching signals, CHA, CHB, based on the chop clock signal 616. These switching signals, CHA, CHB, are used to control the switch network 612 to switch (chop) the input terminals 622a, 622b of the first unity-gain buffer 504a and to internally de-chop the output, as shown in FIG. 6C.

Chopping the two input terminals 622a, 622b of the first unity-gain buffer 504a (and of the second unity-gain buffer 504b) may provide several advantages. Referring again to FIG. 6A, with the first input terminal 622a of the first unity-gain buffer 504a connected as shown (to the output of the first unity-gain buffer 504a via the transistor 502), the voltages at each of the two input terminals 622a, 622b (V+ and V−), may be almost the same. The voltage, V−, at the first input terminal 622a tracks the input voltage V+ at the second input terminal 622b. Accordingly, when the input terminals 622a, 622b are chopped, the chop does not involve switching relatively high voltage differences, and therefore, there may be a relatively low switching current into the input terminals 622a, 622b. In contrast, if input terminals of the two unity-gain buffers 504a, 504b were chopped instead (e.g., alternately connecting the input terminal 622b to the two voltages, V_pos and V_neg) making up the differential input voltage 318 and performing the same switching at the second unity-gain buffer 504b), this would involve potentially switching high voltage differences and therefore involve a high switching current. For example, in some instances, the input voltage V_pos may be 100V and the input voltage V_neg may be 95V. Accordingly, chopping by reversing the polarity of the two unity-gain buffers 504a, 504b may resulting in the input terminals at each unity-gain buffer 504a, 504b toggling at a voltage difference of 5V. This may result in high switching current. Thus, be implementing the chop locally at each unity-gain buffer 504a, 504b individually, as described above, the noise-reduction benefits of the chop can be achieved without requiring high switching currents and/or causing large input leakage current.

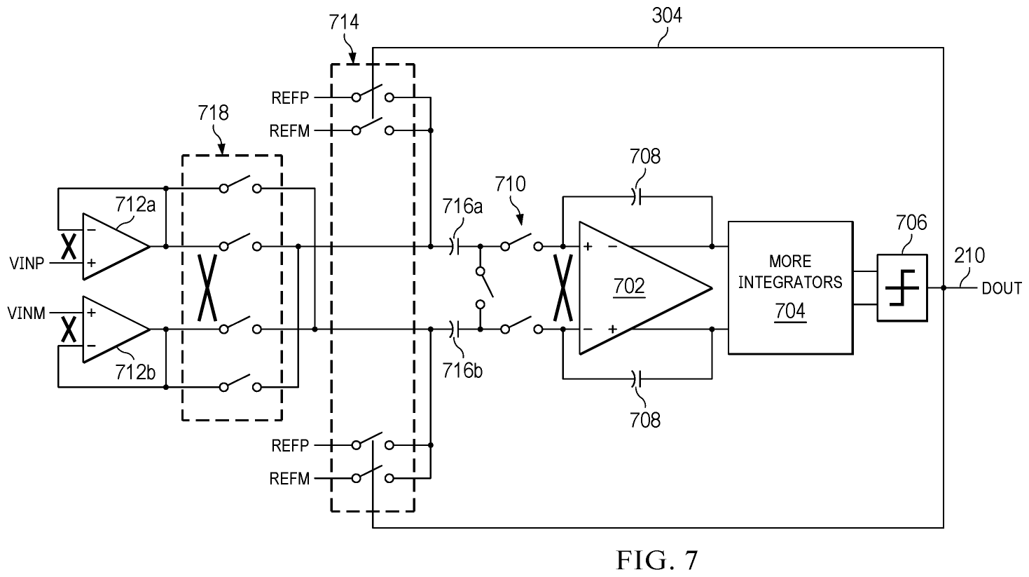

Referring now to FIG. 7, there is illustrated an example of the ADC 304. As described above, in some examples, the ADC 304 is a unity-gain delta-sigma ADC. The ADC 304 may include a first amplifier 702 configured as a switched capacitor integrator. The inputs of the first amplifier 702 may be chopped, as shown, using switches 710. The ADC 704 may include one or more additional integrators 704, depending on the order of the ADC, and an output stage 706. A pair of input buffers 712a, 712b are coupled to the outputs of the differential transimpedance stage 308 to receive the voltages, V_{INP} and V_{INM}, respectively, output from the differential transimpedance stage 308. In some examples, the inputs of these buffers 712a, 712b, may be chopped, as shown, using the chop circuitry 406c of FIG. 4. In addition, connection of the outputs of the buffers 712a, 712b to sampling capacitors 716a, 716b may be chopped using a set of switches 718. The switches 710 and 718 may form part of the chop circuitry 406c, for example.

The delta-sigma ADC operates by comparing samples of the input voltages, V_{INP} and V_{INM}, with reference voltages, REFP, REFM, respectively. In this example, REFP is equal to Vref described above (e.g., +4V) and REFM is ground (e.g., 0V). In the illustrated example, the ADC 304 includes a pair of sampling capacitors 716a, 716b, one for each of the two differential inputs. A set of switches 714 are used to alternately connect the capacitors 716a, 716b to one of the reference voltages, REFP or REFM, or to the outputs of the buffers 712a, 712b, respectively. Thus, at each capacitor 716a, 716b, the ADC 304 may alternately sample the input voltage (V_{INP} or V_{INM}) and the reference voltage (REFP or REFM).

Another configuration may use separate reference sampling capacitors for sampling the reference voltages and input sampling capacitors for sampling the input voltages. However, in this arrangement, capacitor mismatch may be the dominant source of ADC raw error and can cause the gain of the ADC to vary from unity. By using the same capacitor to sample both the input voltage and the reference voltage, as in the configuration illustrated in FIG. 7, the problem of capacitor mismatch is eliminated, and ADC 304 has unity gain. Although there may be some mismatch between the capacitors 716a and 716b, such mismatch may only affect common-mode rejection and not the gain. For unity gain operation, the common-mode voltage level at the inputs 522a, 522b, should be the same as, or otherwise within an acceptable tolerance (e.g., +/−5%, or better, although other examples may have a different tolerance), the reference voltage common-mode level (e.g., 2V in the above example). This is achieved by the output from the transimpedance stage 308 being fully differential, as described above, with the common-mode level set via a feedback path from the ADC reference voltage. For example, a common-mode feedback loop can be implemented to feed the ADC reference voltage common-mode to the transimpedance amplifier 514 to regulate the output from the transimpedance amplifier 514 to match the reference common-mode voltage level.

Thus, aspects and embodiments provide a voltage measurement circuit that implements a fully differential signal chain to provide improved performance over some other voltage measurement devices. As described above, examples of the circuit can accept a differential input voltage range that includes negative voltages (e.g., ˜−3V to +6V), whereas some single-ended designs can only accept positive input voltages. In addition, examples of the circuit may offer improved linearity and reduced gain error, with a relatively clean noise floor. In some examples, the raw error in the signal chain through the analog front-end 302 and the ADC 304 is sufficiently small (e.g., <800μ V) that the need for digital calibration can be avoided. Furthermore, by using chopping to reduce noise and offset, as described above, instead of auto-zero techniques, the ADC 304 may perform true continuous sampling without the disturbance and distortion that can be caused by auto-zeroing.

### Further Examples

Example 1 is a circuit comprising a differential transconductance stage configured to convert a differential input voltage into a differential current, a differential transimpedance stage configured to convert the differential current into a differential output voltage, a common-mode voltage regulator configured to regulate a common-mode input voltage for the differential transimpedance stage, and an analog-to-digital converter configured to sample the differential output voltage to produce a digital output signal.

Example 2 includes the circuit of Example 1, further comprising an offset stage configured to adjust the differential current converted by the differential transimpedance stage, based on an input range of the analog-to-digital converter, to reduce input-referred error of the analog-to-digital converter.

Example 3 includes the circuit of one of Examples 1 or 2, wherein the analog-to-digital converter is a unity gain delta-sigma analog-to-digital converter.

Example 4 includes the circuit of any one of Examples 1-3, wherein the differential transimpedance stage comprises a differential transimpedance amplifier, and a resistive-capacitive filter coupled between differential output terminals of the differential transimpedance amplifier and differential input terminals of the analog-to-digital converter.

Example 5 includes the circuit of any one of Examples 1-4, wherein the differential transconductance stage comprises first and second unity gain buffers and a resistor coupled between the first and second unity gain buffers.

Example 6 includes the circuit of Example 5, wherein the differential transconductance stage comprises a first transistor coupled between a voltage supply terminal and a first differential input terminal of the differential transimpedance stage, and a second transistor coupled between the voltage supply terminal and a second differential input terminal of the differential transimpedance stage, wherein the first unity gain buffer has a first input terminal coupled to a first input voltage terminal, a second input terminal coupled to the voltage supply terminal, and an output terminal coupled to a control terminal of the first transistor, wherein the second unity gain buffer has a first input terminal coupled to a second input voltage terminal, a second input terminal coupled to the voltage supply terminal, and an output terminal coupled to a control terminal of the second transistor, and wherein the resistor is coupled between the second input terminal of the first unity gain buffer and the second input terminal of the second unity gain buffer.

Example 7 includes the circuit of Example 6 and comprising a first chop circuit coupled to a chop clock terminal and configured to switch the first and second input terminals of the first unity gain buffer based on a frequency of a chop clock signal received via the chop clock terminal, and a second chop circuit coupled to the chop clock terminal and configured to switch the first and second input terminals of the second unity gain buffer based on the frequency of the chop clock signal.

Example 8 includes the circuit of Example 7, wherein each of the first and second chop circuits comprises transistor circuitry configured to generate a floating voltage supply and a floating voltage reference based on a pin voltage of a respective one of the first or second unity gain buffers, a plurality of switches, digital logic circuitry configured to produce switching signals to control operation of the plurality of switches based on the chop clock signal, the switching signals transitioning between the floating voltage supply and the floating voltage reference to open and close the plurality of switches, and one or more capacitors coupled between the chop clock terminal and the digital logic circuitry.

Example 9 includes the circuit of any one of Examples 1-8, wherein the differential transconductance stage is configured to operate in a first voltage domain, and the differential transimpedance stage is configured to operate in a second voltage domain, and voltages of the first voltage domain are higher than voltages of the second voltage domain.

Example 10 includes the circuit of any one of Examples 1-9, wherein the differential transconductance stage is a high-voltage differential transconductance stage and the differential transimpedance stage is a low-voltage differential transimpedance stage, in that a first voltage and a second voltage of the differential input voltage are higher than a first voltage and a second voltage of the differential output voltage.

Example 11 is a battery monitor system comprising the circuit of any one of Examples 1-10.

Example 12 is a stackable battery monitor apparatus comprising the battery monitor system of Example 11.

Example 13 provides a system comprising a battery pack comprising a plurality of battery cells, and a plurality of battery monitor circuits, individual battery monitor circuits coupled to one or more battery cells of the plurality of battery cells, wherein each battery monitor circuit includes the circuit of any one of Examples 1-10.

Example 14 provides a circuit comprising a differential transimpedance amplifier having a first input terminal, a second input terminal, a first output terminal, and second output terminal. The circuit further comprises a differential transconductance stage including a first transistor coupled in series between a voltage supply terminal and the first input terminal of the differential transimpedance amplifier, a second transistor coupled in series between the voltage supply terminal and the second input terminal of the differential transimpedance amplifier, a first unity gain buffer having a first input terminal coupled to a first input voltage terminal, a second input terminal coupled to the voltage supply terminal, and an output coupled to a control terminal of the first transistor, a second unity gain buffer having a first input terminal coupled to a second input voltage terminal, a second input terminal coupled to the voltage supply terminal, and an output coupled to a control terminal of the second transistor, and a resistor coupled between the second input terminal of the first unity gain buffer and the second input terminal of the second unity gain buffer. The circuit further comprises an analog-to-digital converter having a first input terminal and a second input terminal coupled to the first output terminal and the second output terminal, respectively, of the differential transimpedance amplifier.

Example 15 includes the circuit of Example 14, comprising a common-mode voltage regulator coupled to the first and second input terminals of the differential transimpedance amplifier.

Example 16 includes the circuit of one of Examples 14 or 15, further comprising a voltage offset circuit coupled to the second input terminal of the differential transimpedance amplifier.

Example 17 includes the circuit of Example 16, wherein the resistor is a first resistor, and the voltage offset circuit comprises a second resistor, a third transistor coupled in series between the second input terminal of the differential transimpedance amplifier and a first resistor terminal of the second resistor, a fourth transistor coupled in series between a second resistor terminal of the second resistor and a ground terminal, a first amplifier having a first input terminal coupled to a first reference voltage terminal, a second input terminal coupled to the first resistor terminal, and an output terminal coupled to a control terminal of the third transistor, and a second amplifier having a first input terminal coupled to a second reference voltage terminal, a second input terminal coupled to the second resistor terminal, and an output terminal coupled to a control terminal of the fourth transistor.

Example 18 includes the circuit of any one of Examples 14-17, comprising a resistive-capacitive filter coupled between the first and second output terminals of the differential transimpedance amplifier and the first and second input terminals of the analog-to-digital converter.

Example 19 includes the circuit of Example 18, wherein the resistive-capacitive filter comprises a first resistor coupled between the first output terminal of the differential transimpedance amplifier and the first input terminal of the analog-to-digital converter, a second resistor coupled between the second output terminal of the differential transimpedance amplifier and the second input terminal of the analog-to-digital converter, and a capacitor coupled between the first and second input terminals of the analog-to-digital converter.

Example 20 includes the circuit of any one of Examples 14-19, wherein the analog-to-digital converter is a unity gain delta-sigma analog-to-digital converter.

Example 21 includes the circuit of any one of Examples 14-20, comprising a chop circuit configured to switch the first and second input terminals of the first unity gain buffer according to a chop frequency. The chop circuit includes transistor circuitry configured to generate, based on a pin voltage received at the first input terminal of the first unity gain buffer, a floating supply voltage and a floating reference voltage, a plurality of switches coupled to the first and second input terminals of the first unity gain buffer, digital logic circuitry coupled to the plurality of switches and to a chop clock terminal, the digital logic circuitry configured to control operation of the plurality of the switches based on a chop clock signal received via the chop clock terminal to switch the first and second input terminals of the first unity gain buffer, wherein the chop clock signal has the chop frequency, and one or more capacitors coupled between the chop clock terminal and the digital logic circuitry.

Example 22 includes the circuit of Example 21, wherein to control the operation of the plurality of switches, the digital logic circuitry is configured to produce one or more switching signals that transition between the floating supply voltage and the floating reference voltage to open and close the plurality of switches based on the chop frequency.

Example 23 provides a circuit comprising a differential transconductance stage configured to produce a differential current based on first and second input voltages received at first and second input voltage terminals, respectively, and a differential transimpedance stage coupled to the differential transconductance stage and configured to convert the differential current into a differential output voltage. The differential transconductance stage comprises a first unity gain buffer having a first and second input terminals switchably coupled to the first input voltage terminal and a voltage supply terminal, a second unity gain buffer having first and second input terminals switchably coupled to the second input voltage terminal and the voltage supply terminal, and a resistor coupled between the first and second unity gain buffers. The circuit further comprises chop circuitry having a clock terminal and configured to switch the first and second input terminals of each of the first and second unity gain buffers according to a frequency of a chop clock signal received via the clock terminal.

Example 24 includes the circuit of Example 23, wherein the chop circuitry comprises a first chop circuit and a second chop circuit. The first chop circuit comprises first transistor circuitry configured to generate a first floating voltage supply and a first floating voltage reference based on the first input voltage, a first plurality of switches configured to switch the first and second input terminals of the first unity gain buffer between connection to the first input voltage terminal and connection to the voltage supply terminal, first digital logic circuitry configured to produce, using the first floating voltage supply and the first floating voltage reference, one or more first switching signals to control operation of the first plurality of switches based on the chop clock signal, and one or more first capacitors coupled between the clock terminal and the first digital logic circuitry. The second chop circuit comprises second transistor circuitry configured to generate a second floating voltage supply and a second floating voltage reference based on the second input voltage, a second plurality of switches configured to switch the first and second input terminals of the second unity gain buffer between connection to the second input voltage terminal and connection to the voltage supply terminal, second digital logic circuitry configured to produce, using the second floating voltage supply and the second floating voltage reference, one or more second switching signals to control operation of the second plurality of switches based on the chop clock signal, and one or more second capacitors coupled between the clock terminal and the second digital logic circuitry.

Example 25 is a circuit comprising a resistor having a first resistor terminal and a second resistor terminal, a first current source coupled between a high-voltage power supply and the first resistor terminal, a second current source coupled between the high-voltage power supply and the second resistor terminal, and first and second chopped amplifiers that buffer a differential input voltage across the resistor. A voltage output terminal of the first chopped amplifier is coupled to the first resistor terminal, and a voltage output of the second chopped amplifier is coupled to the second resistor terminal. Each of the first and second chopped amplifiers includes a positive input terminal and a negative input terminal, wherein each amplifier input is chopped on the positive and negative input terminals and the polarity of the output voltage from the amplifiers, offset across the resistor, is reversed with each chopping.

In this description, the term “couple” may cover connections, communications, or signal paths that enable a functional relationship consistent with this description. For example, if device A generates a signal to control device B to perform an action: (a) in a first example, device A is coupled to device B by direct connection; or (b) in a second example, device A is coupled to device B through intervening component C if intervening component C does not alter the functional relationship between device A and device B, such that device B is controlled by device A via the control signal generated by device A.

A device that is “configured to” perform a task or function may be configured (e.g., programmed and/or hardwired) at a time of manufacturing by a manufacturer to perform the function and/or may be configurable (or reconfigurable) by a user after manufacturing to perform the function and/or other additional or alternative functions. The configuring may be through firmware and/or software programming of the device, through a construction and/or layout of hardware components and interconnections of the device, or a combination thereof.

As used herein, the terms “terminal,” “node,” “interconnection,” “pin,” and “lead” are used interchangeably. Unless specifically stated to the contrary, these terms are generally used to mean an interconnection between or a terminus of a device element, a circuit element, an integrated circuit, a device or other electronics or semiconductor component.

A circuit or device that is described herein as including certain components may instead be adapted to be coupled to those components to form the described circuitry or device. For example, a structure described as including one or more semiconductor elements (such as transistors), one or more passive elements (such as resistors, capacitors, and/or inductors), and/or one or more sources (such as voltage and/or current sources) may instead include only the semiconductor elements within a single physical device (e.g., a semiconductor die and/or integrated circuit (IC) package) and may be adapted to be coupled to at least some of the passive elements and/or the sources to form the described structure either at a time of manufacture or after a time of manufacture, such as by an end user and/or a third party.

While the use of particular transistors is described herein, other transistors (or equivalent devices) may be used instead. For example, a p-channel field effect transistor (PFET) may be used in place of an n-channel field effect transistor (NFET) with little or no changes to the circuit. Furthermore, other types of transistors may be used (such as bipolar junction transistors (BJTs)). Furthermore, the devices may be implemented in/over a silicon substrate (Si), a silicon carbide substrate (SiC), a gallium nitride substrate (GaN) or a gallium arsenide substrate (GaAs). Moreover, reference to transistor features such as gate, source, or drain is not intended to exclude any suitable transistor technologies. For instance, features such as source, drain, and gate are typically used to refer to a FET, while emitter, collector, and base are typically used to refer to a BJT. Such features may be used interchangeably herein. For instance, reference to the gate of a transistor may refer to either the gate of a FET or the base of a BJT, and vice-versa. In some examples, a control terminal may refer to either the gate of a FET or the base of a BJT. Any other suitable transistor technologies can be used. Any such transistors can be used as a switch, with the gate or base or other comparable feature acting as a switch select input that can be driven to connect the source and drain (or the emitter and collector, as the case may be).

References herein to a field effect transistor (FET) being “ON” (or a switch being closed) means that the conduction channel of the FET is present, and drain current may flow through the FET. References herein to a FET being “OFF” (or a switch being open) means that the conduction channel is not present, and drain current does not flow through the FET. A FET that is OFF, however, may have current flowing through the transistor's body-diode.

Circuits described herein are reconfigurable to include additional or different components to provide functionality at least partially similar to functionality available prior to the component replacement. Components shown as resistors, unless otherwise stated, are generally representative of any one or more elements coupled in series and/or parallel to provide an amount of impedance represented by the resistor shown. For example, a resistor or capacitor shown and described herein as a single component may instead be multiple resistors or capacitors, respectively, coupled in parallel between the same nodes. For example, a resistor or capacitor shown and described herein as a single component may instead be multiple resistors or capacitors, respectively, coupled in series between the same two nodes as the single resistor or capacitor.

Uses of the phrase “ground” in the foregoing description include a chassis ground, an Earth ground, a floating ground, a virtual ground, a digital ground, a common ground, and/or any other form of ground connection applicable to, or suitable for, the teachings of this description. In this description, unless otherwise stated, “about,” “approximately” or “substantially” preceding a parameter means being within +/−10 percent of that parameter.

Modifications are possible in the described examples, and other examples are possible within the scope of the claims.

What is claimed is:

1. A circuit comprising:
a differential transconductance stage configured to convert a differential input voltage into a differential current;
a differential transimpedance stage configured to convert the differential current into a differential output voltage;
a common-mode voltage regulator configured to regulate a common-mode input voltage for the differential transimpedance stage; and
an analog-to-digital converter configured to sample the differential output voltage to produce a digital output signal.

2. The circuit of claim 1, comprising:
an offset stage configured to adjust the differential current converted by the differential transimpedance stage, based on an input range of the analog-to-digital converter, to reduce input-referred error of the analog-to-digital converter.

3. The circuit of claim 1, wherein the analog-to-digital converter is a unity gain delta-sigma analog-to-digital converter.

4. The circuit of claim 1, wherein the differential transimpedance stage comprises:
a differential transimpedance amplifier; and
a resistive-capacitive filter coupled between differential output terminals of the differential transimpedance amplifier and differential input terminals of the analog-to-digital converter.

5. The circuit of claim 1, wherein the differential transconductance stage comprises:
a first transistor coupled between a voltage supply terminal and a first differential input terminal of the differential transimpedance stage;
a second transistor coupled between the voltage supply terminal and a second differential input terminal of the differential transimpedance stage;
a first unity gain buffer having a first input terminal coupled to a first input voltage terminal, a second input terminal coupled to the voltage supply terminal, and an output terminal coupled to a control terminal of the first transistor;
a second unity gain buffer having a first input terminal coupled to a second input voltage terminal, a second input terminal coupled to the voltage supply terminal, and an output terminal coupled to a control terminal of the second transistor; and
a resistor is coupled between the second input terminal of the first unity gain buffer and the second input terminal of the second unity gain buffer.

6. The circuit of claim 5, comprising:
a first chop circuit coupled to a chop clock terminal and configured to switch the first and second input terminals of the first unity gain buffer based on a frequency of a chop clock signal received via the chop clock terminal; and
a second chop circuit coupled to the chop clock terminal and configured to switch the first and second input terminals of the second unity gain buffer based on the frequency of the chop clock signal.

7. The circuit of claim 6, wherein each of the first and second chop circuits comprises:
transistor circuitry configured to generate a floating voltage supply and a floating voltage reference based on a pin voltage of a respective one of the first or second unity gain buffers;
a plurality of switches;
digital logic circuitry configured to produce switching signals to control operation of the plurality of switches based on the chop clock signal, the switching signals transitioning between the floating voltage supply and the floating voltage reference to open and close the plurality of switches; and
one or more capacitors coupled between the chop clock terminal and the digital logic circuitry.

8. The circuit of claim 1, wherein the differential transconductance stage is configured to operate in a first voltage domain, and the differential transimpedance stage is configured to operate in a second voltage domain, and voltages of the first voltage domain are higher than voltages of the second voltage domain.

9. The circuit of claim 1, wherein the differential transconductance stage is a high-voltage differential transconductance stage and the differential transimpedance stage is a low-voltage differential transimpedance stage, in that a first voltage and a second voltage of the differential input voltage are higher than a first voltage and a second voltage of the differential output voltage.

10. A system comprising:
a battery pack comprising a plurality of battery cells; and
a plurality of battery monitor circuits, individual battery monitor circuits coupled to one or more battery cells of the plurality of battery cells;
wherein each battery monitor circuit includes the circuit of claim 1.

11. A circuit comprising:
a differential transimpedance amplifier having a first input terminal, a second input terminal, a first output terminal, and second output terminal;
a differential transconductance stage including
a first transistor coupled in series between a voltage supply terminal and the first input terminal of the differential transimpedance amplifier,
a second transistor coupled in series between the voltage supply terminal and the second input terminal of the differential transimpedance amplifier,
a first unity gain buffer having a first input terminal coupled to a first input voltage terminal, a second input terminal coupled to the voltage supply terminal, and an output coupled to a control terminal of the first transistor,
a second unity gain buffer having a first input terminal coupled to a second input voltage terminal, a second input terminal coupled to the voltage supply terminal, and an output coupled to a control terminal of the second transistor, and
a resistor coupled between the second input terminal of the first unity gain buffer and the second input terminal of the second unity gain buffer; and
an analog-to-digital converter having a first input terminal and a second input terminal coupled to the first output terminal and the second output terminal, respectively, of the differential transimpedance amplifier.

12. The circuit of claim 11, comprising:
a common-mode voltage regulator coupled to the first and second input terminals of the differential transimpedance amplifier.

13. The circuit of claim 11, further comprising:
a voltage offset circuit coupled to the second input terminal of the differential transimpedance amplifier.

14. The circuit of claim 13, wherein the resistor is a first resistor, and the voltage offset circuit comprises:
a second resistor;
a third transistor coupled in series between the second input terminal of the differential transimpedance amplifier and a first resistor terminal of the second resistor;
a fourth transistor coupled in series between a second resistor terminal of the second resistor and a ground terminal;
a first amplifier having a first input terminal coupled to a first reference voltage terminal, a second input terminal coupled to the first resistor terminal, and an output terminal coupled to a control terminal of the third transistor; and
a second amplifier having a first input terminal coupled to a second reference voltage terminal, a second input terminal coupled to the second resistor terminal, and an output terminal coupled to a control terminal of the fourth transistor.

15. The circuit of claim 11, wherein the analog-to-digital converter is a unity gain delta-sigma analog-to-digital converter.

16. The circuit of claim 11, comprising:
a resistive-capacitive filter coupled between the first and second output terminals of the differential transimpedance amplifier and the first and second input terminals of the analog-to-digital converter;
wherein the resistive-capacitive filter comprises
a first resistor coupled between the first output terminal of the differential transimpedance amplifier and the first input terminal of the analog-to-digital converter,
a second resistor coupled between the second output terminal of the differential transimpedance amplifier and the second input terminal of the analog-to-digital converter, and
a capacitor coupled between the first and second input terminals of the analog-to-digital converter.

17. The circuit of claim 11, comprising:
a chop circuit configured to switch the first and second input terminals of the first unity gain buffer according to a chop frequency, the chop circuit including
transistor circuitry configured to generate, based on a pin voltage received at the first input terminal of the first unity gain buffer, a floating supply voltage and a floating reference voltage;
a plurality of switches coupled to the first and second input terminals of the first unity gain buffer;
digital logic circuitry coupled to the plurality of switches and to a chop clock terminal, the digital logic circuitry configured to control operation of the plurality of the switches based on a chop clock signal received via the chop clock terminal to switch the first and second input terminals of the first unity gain buffer, wherein the chop clock signal has the chop frequency; and
one or more capacitors coupled between the chop clock terminal and the digital logic circuitry.

18. The circuit of claim 17, wherein to control the operation of the plurality of switches, the digital logic circuitry is configured to produce one or more switching signals that transition between the floating supply voltage and the floating reference voltage to open and close the plurality of switches based on the chop frequency.

19. A circuit comprising:
a differential transconductance stage configured to produce a differential current based on first and second input voltages received at first and second input voltage terminals, respectively, the differential transconductance stage comprising
a first unity gain buffer having a first and second input terminals switchably coupled to the first input voltage terminal and a voltage supply terminal,
a second unity gain buffer having first and second input terminals switchably coupled to the second input voltage terminal and the voltage supply terminal, and
a resistor coupled between the first and second unity gain buffers;
a differential transimpedance stage coupled to the differential transconductance stage and configured to convert the differential current into a differential output voltage; and
chop circuitry having a clock terminal and configured to switch the first and second input terminals of each of the first and second unity gain buffers according to a frequency of a chop clock signal received via the clock terminal.

20. The circuit of claim 19, wherein the chop circuitry comprises:
a first chop circuit comprising
first transistor circuitry configured to generate a first floating voltage supply and a first floating voltage reference based on the first input voltage,
a first plurality of switches configured to switch the first and second input terminals of the first unity gain buffer between connection to the first input voltage terminal and connection to the voltage supply terminal,
first digital logic circuitry configured to produce, using the first floating voltage supply and the first floating voltage reference, one or more first switching signals to control operation of the first plurality of switches based on the chop clock signal, and
one or more first capacitors coupled between the clock terminal and the first digital logic circuitry; and
a second chop circuit comprising
second transistor circuitry configured to generate a second floating voltage supply and a second floating voltage reference based on the second input voltage,
a second plurality of switches configured to switch the first and second input terminals of the second unity gain buffer between connection to the second input voltage terminal and connection to the voltage supply terminal,
second digital logic circuitry configured to produce, using the second floating voltage supply and the second floating voltage reference, one or more second switching signals to control operation of the second plurality of switches based on the chop clock signal, and
one or more second capacitors coupled between the clock terminal and the second digital logic circuitry.
